(19) United States
(12) Patent Application Publication
(10) Pub. No.: US 2009/0102065 A1
(43) Pub. Date: Apr. 23, 2009

(54) BONDING PAD FOR ANTI-PEELING PROPERTY AND METHOD FOR FABRICATING THE SAME

(75) Inventor: In-Chan LEE, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Ichon-shi (KR)

(21) Appl. No.: 12/165,235

(22) Filed: Jun. 30, 2008

(30) Foreign Application Priority Data
Oct. 22, 2007 (KR) 10-2007-0106044

(51) Int. Cl. H01L 23/485; H01L 21/768

(52) U.S. Cl. 257/784; 438/612; 257/E23.02; 257/E21.585; 257/E21.59

(57) ABSTRACT

A bonding pad includes an insulation layer with a trench, and a conductive pattern one portion of which is buried into the trench and the other portion of which is formed in a plate shape over the insulation layer.

### CROSS-REFERENCE TO RELATED APPLICATIONS

The present invention claims priority of Korean patent application number 2007-0106044, filed on Oct. 22, 2007, which is incorporated by reference in its entirety.

### BACKGROUND OF THE INVENTION

The present invention relates to a method for fabricating a semiconductor device, and more particularly, to a bonding pad for preventing a bonding pad unit from being peeled during wire bonding and a method for fabricating the same.

Generally, in a packaging process of a semiconductor device, wire bonding is a process of electrically connecting a metal pad of a bonding pad unit on a chip to a lead frame which connects to an external device. To be specific, ball bonding is performed over the metal pad during the wire bonding. The bonding pad unit for bonding includes a plurality of metal layers and an insulation layer of metal layers.

FIG. 1 is a cross-sectional view of a typical bonding pad.

Referring to FIG. 1, a first metal layer 12, a second metal layer 14, and a third metal layer 16 are formed over a substrate 11 with a certain structure. A first insulation layer 13 is formed between the first metal layer 12 and the second metal layer 14. A second insulation layer 15 is formed between the second metal layer 14 and the third metal layer 16. The wire bonding is performed on the third metal layer 16. That is, the third metal layer 16 functions as a bonding pad.

However, according to the typical method, the second insulation layer 15 is a spin on glass (SOG) layer. Since the SOG layer includes impurities such as carbon (C), the hardness of the SOG layer is low. Furthermore, due to a height difference between the SOG layer and the second metal layer 14, the SOG layer may be formed thick in one region and thin in another region. Thus, a stress is generated in the SOG layer. The bonding pad unit cannot stand physical impact applied during wire bonding or proving for device testing performed before/after the packaging process.

FIGS. 2A and 2B are micrographic views showing limitations of a typical bonding pad.

Referring to FIGS. 2A and 2B, the third metal layer 16 and the second insulation layer 15 below the third metal layer 16 are peeled off. The peeling of the pad may drop the throughput of the semiconductor devices.

### SUMMARY OF THE INVENTION

Embodiments of the present invention relate to a bonding pad for preventing a bonding pad unit from being peeled during wire bonding and a method for fabricating the same.

This invention increases contact area between a bonding pad and a lower insulation layer to alleviate physical shock applied to a bonding pad unit during wire bonding or testing.

Furthermore, a metal layer below the bonding pad is removed to form the insulation layer to have a regular thickness. Thus, stress is less generated in the insulation layer and resistance to the physical shock applied to the bonding pad unit increases.

In accordance with an aspect of the present invention, there is provided a bonding pad including an insulation layer with a trench, and a conductive pattern one portion of which is buried into the trench and the other portion of which is formed in a plate shape over the insulation layer.

In accordance with another aspect of the present invention, there is provided a method for fabricating a bonding pad. The method includes providing a substrate, forming an insulation layer over the substrate, forming a trench by selectively etching the insulation layer; and forming a conductive pattern to have one portion buried into the trench and the other portion formed in a plate shape over the insulation layer.

### BRIEF DESCRIPTION OF THE DRAWINGS

FIG. 1 is a cross-sectional view of a typical bonding pad.

FIGS. 2A and 2B are micrographic views showing limitations of a typical bonding pad.

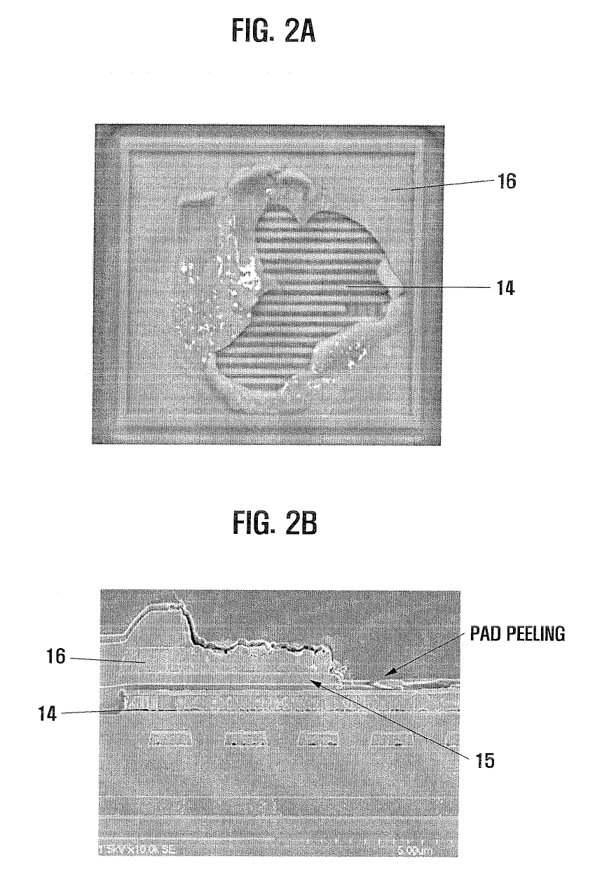

FIG. 3 is a cross-sectional view of a bonding pad in accordance with an embodiment of the present invention.

FIGS. 4A to 4F are plane views showing plate shapes of a trench in accordance with an embodiment of the present invention.

FIGS. 5A and 5B are cross-sectional views describing a method for fabricating a bonding pad in accordance with an embodiment of the present invention.

### DESCRIPTION OF SPECIFIC EMBODIMENTS

Embodiments of the present invention relate to a bonding pad for preventing pad peeling and a method for fabricating the same.

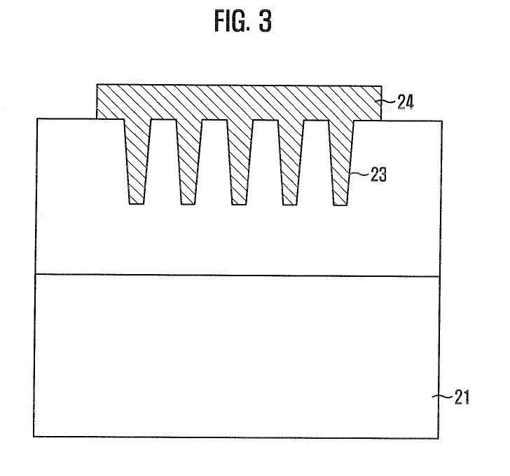

FIG. 3 is a cross-sectional view of a bonding pad in accordance with an embodiment of the present invention.

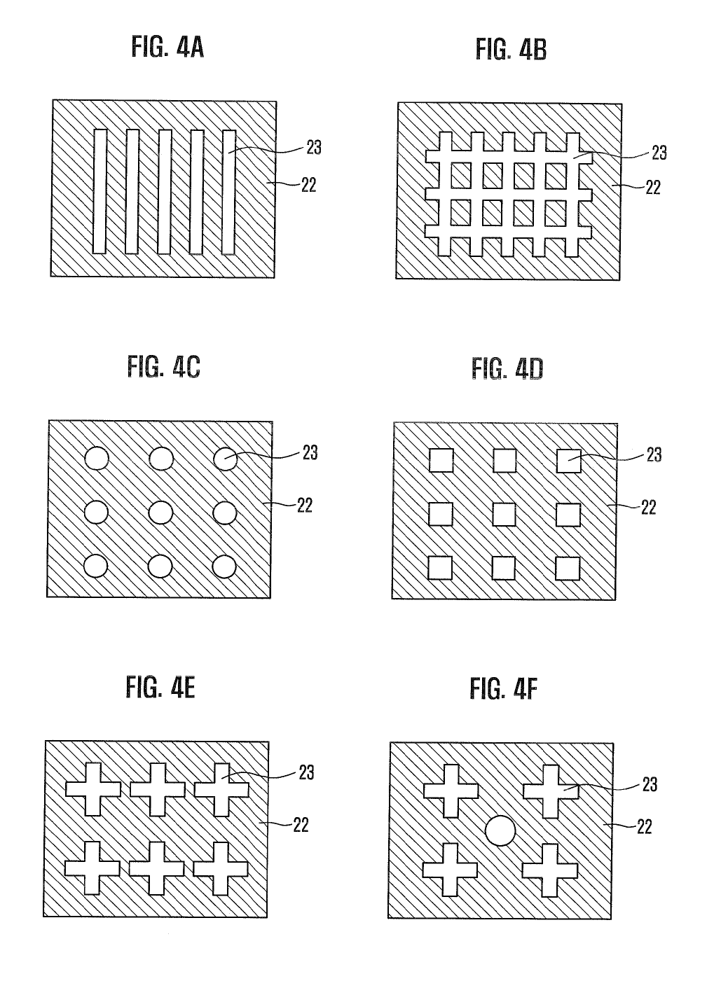

FIGS. 4A to 4F are plane views showing plate shapes of a trench in accordance with an embodiment of the present invention.

Referring to FIGS. 3 to 4F, in the bonding pad, an insulation layer 22 with a trench 23 thereon and a conductive pattern 24 are formed over a substrate 21 with a certain structure. One portion of the conductive pattern 24 is buried into the trench 23 and the other portion of the conductive pattern 24 is formed in a plate shape over the insulation layer 22. The conductive pattern 24 may include a metal layer, e.g., an aluminum (Al) layer. The insulation layer 22 may include an oxide layer, e.g., a SOG layer.

The trench 23 may be formed to increase contact area between the insulation layer 22 and the conductive pattern 24. For instance, the trench 23 may be formed to have a plurality of slits (see FIG. 4A) or to have a matrix form (see FIG. 4B). The trench 23 may also be formed in a plurality of arranged shapes selected from a group consisting of a circle, square, cross (see FIGS. 4C to 4E) and a combination thereof (see FIG. 4F).

Herein, a linewidth (or critical dimension) of the trench 23 is changed according to a thickness of a conductive pattern 24 to be formed through a subsequent process. Specifically, the linewidth of the trench 23 may be formed to be the same as or greater than the thickness of the conductive pattern 24 formed over the insulation layer 24. For instance, the linewidth of the trench 23 may be approximately 100% to approximately 200% as wide as the thickness of the conductive pattern 24 formed over the insulation layer 22. If the linewidth of the trench 23 is less than the thickness of the conductive pattern 24, a height difference can occur when the trench 23 is filled during a deposition of the conductive layer. The height difference can cause the bonding defect during the bonding process. Furthermore, when the linewidth of the trench 23 is approximately 200% as wide as the thickness of the conductive pattern 24, the conductive layer cannot sufficiently fill the trench 23 during a formation of the conductive pattern 24. That is, a filling defect occurs.

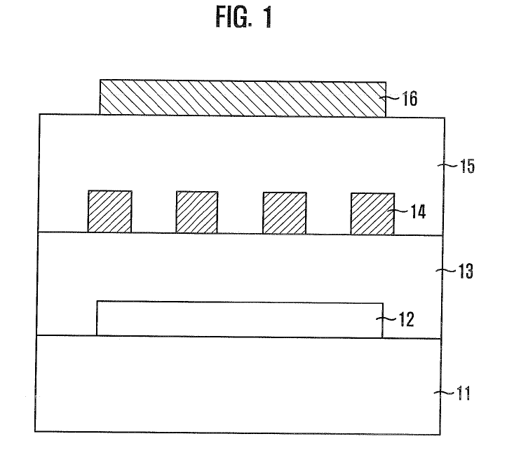

In this embodiment, a metal layer below the conductive pattern 24, i.e., the second metal layer 14 in FIG. 1, is removed and the insulation layer 22 below the conductive pattern 24, i.e., the second insulation layer 15 in FIG. 1, is formed to have a regular thickness. Thus, this causes less stress in the insulation layer 22.

In this invention, a structure of the bonding pad, i.e. the conductive pattern 24, is changed to increase the contact area between the insulation layer 22 and the conductive pattern 24. Thus, the peeling of the bonding pad and the insulation layer 22 caused by physical shock applied during the wire bonding or semiconductor device testing can be prevented. Thus, throughput of the semiconductor device increases.

Furthermore, the metal layer below the conductive pattern 24 is removed and the insulation layer 22 adjacent to the conductive pattern 24 is formed to have a regular thickness. Thus, the stress is reduced in the insulation layer 22. As a result, a resistance to the physical shock applied to the bonding pad during the wire bonding or semiconductor device testing increases.

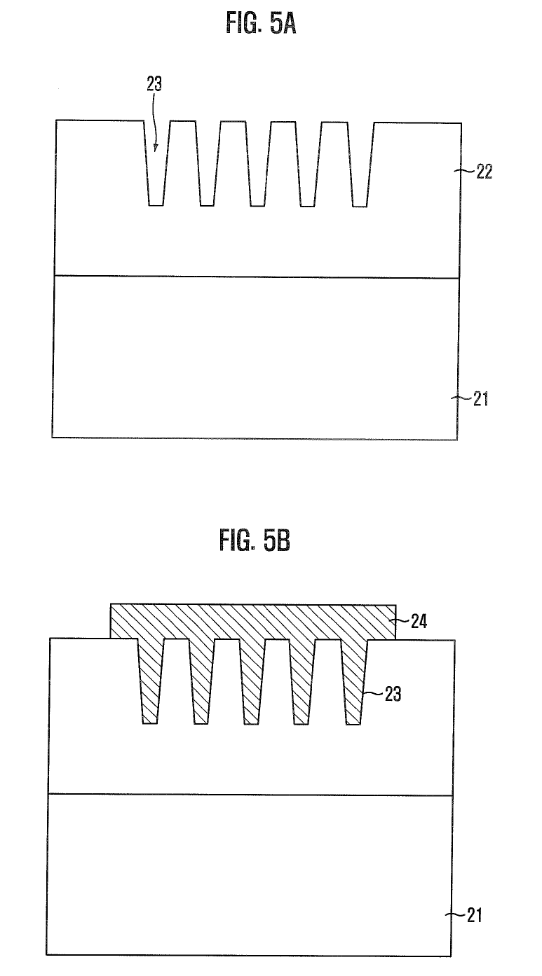

FIGS. 5A and 5B are cross-sectional views describing a method for fabricating a bonding pad in accordance with an embodiment of the present invention.

Referring to FIG. 5A, an insulation layer 22 is formed over a substrate 21 with a certain structure. The insulation layer 22 may be an oxide layer, i.e., a SOG layer. Also, the insulation layer 22 may be one of a silicon oxide (SiO₂) layer, a boron phosphorus silicate glass (BPSG) layer, a phosphorus silicate glass (PSG) layer, a tetra ethyle ortho silicate (TEOS) layer, an un-doped silicate glass (USG) layer, a high density plasma (HDP), a spin on dielectric (SOD) layer, and a combination thereof.

Before the formation of the insulation layer 22, the metal layers below the region to be the bonding pad are removed. The insulation layer 22 in the region to be the bonding pad does not include metal layers such as the second metal layer 14 and the first metal layer 12 in FIG. 1.

A photoresist pattern is formed over the insulation layer 22. The insulation layer 22 is etched using the photoresist pattern as an etch barrier to form a trench 23. The trench 23 may be formed to have a shape that increases the contact area between the bonding pad (to be formed in a subsequent process) and the insulation layer 22. The trench 23 may be formed to have a plurality of slits or to have a matrix form. For instance, the trench 23 may be formed to have a plurality of slits (see FIG. 4A) or to have a matrix form (see FIG. 4B). The trench 23 may also be formed in a plurality of arranged shapes from a group consisting of a circle, square, cross (see FIGS. 4C to 4E) and a combination thereof (see FIG. 4F).

Herein, a linewidth of the trench 23 is changed according to a thickness of a conductive pattern 24 to be formed through a subsequent process. For instance, the linewidth of the trench 23 is approximately 100% to approximately 200% as wide as the thickness of the conductive pattern 24 formed over the insulation layer 22. If the linewidth of the trench 23 is smaller than the thickness of the conductive pattern 24, a great height difference can be generated when the trench 23 is filled for a deposition of the conductive layer. The height difference can cause the bonding defect during the bonding process. Furthermore, when the linewidth of the trench 23 is approximately 200% as wide as the thickness of the conductive pattern 24, the conductive layer cannot sufficiently fill the trench 23 for a formation of the conductive pattern 24. That is, a filling fail occurs.

Referring to FIG. 5B, a conductive pattern 24 is formed over the insulation layer 22 with the trench 23. The conductive pattern 24 functions as a bonding pad. One portion of the conductive pattern 24 is buried into the trench 23 and the other portion of the conductive pattern 24 is formed over the insulation layer 22 to have a plate shape. The conductive pattern 24 may include a metal, e.g. an Al layer.

Although not shown, a protection layer is formed to expose a portion of the conductive pattern 24. Then, wire bonding or semiconductor device testing may be performed.

As described, a structure of the bonding pad, i.e. the conductive pattern 24, changes to increase contact area between the insulation layer 22 and the conductive pattern 24. Thus, the peeling of the bonding pad and the insulation 22 caused by physical shock applied during the wire bonding or semiconductor device testing can be prevented. Thus, throughput of the semiconductor device increases.

Furthermore, the metal layer below the conductive pattern 24 is removed and the insulation layer 22 adjacent to the conductive pattern 24 is formed to have a regular thickness. Thus, the stress is reduced in the insulation layer 22. As a result, a resistance to the physical shock applied to the bonding pad during the wire bonding or semiconductor device testing increases.

While the present invention has been described with respect to the specific embodiments, the above embodiments of the present invention are illustrative and not limitative. It will be apparent to those skilled in the art that various changes and modifications may be made without departing from the spirit and scope of the invention as defined in the following claims.

What is claimed is:

1. A bonding pad, comprising:
an insulation layer having a trench; and
a conductive pattern having a first portion and a second portion, the first portion being provided within the trench and the second portion being formed in a plate shape over the insulation layer.

2. The bonding pad of claim 1, wherein the trench defines a matrix form when seen from top.

3. The bonding pad of claim 1, wherein the trench defines a plurality of slits.

4. The bonding pad of claim 1, wherein the trench a plate shape that a plurality of one of circle, square, cross and a combination thereof are arranged therein.

5. The bonding pad of claim 2, wherein the linewidth of the trench is as wide as the thickness of the conductive pattern formed over the insulation layer.

6. The bonding pad of claim 1, wherein the conductive pattern is a metal layer.

7. The bonding pad of claim 1, wherein the conductive pattern includes an aluminum (Al) layer.

8. The bonding pad of claim 1, wherein the insulation layer includes an oxide layer.

9. The bonding pad of claim 1, wherein the insulation layer includes a spin on glass (SOG) layer.

10. A method for fabricating a bonding pad, the method comprising:
providing a substrate;
forming an insulation layer over the substrate;
forming a trench in the insulation layer by selectively etching the insulation layer; and
forming a conductive pattern having a first portion and a second portion, the first portion being provided within the trench and the second portion being formed in a plate shape over the insulation layer.

11. The method of claim 10, wherein the trench defines a matrix form.

12. The method of claim 10, wherein the trench includes a plurality of slits arranged therein.

13. The method of claim 10, wherein the trench defines a circle, a square, a cross, or a combination thereof.

14. The method of claim 11, wherein the linewidth of the trench is as wide as the thickness of the conductive pattern formed over the insulation layer.

15. The method of claim 10, wherein the conductive pattern includes a metal layer.

16. The method of claim 10, wherein the conductive pattern includes an Al layer.

17. The method of claim 10, wherein the insulation layer includes an oxide layer.

18. The method of claim 10, wherein the insulation layer includes a SOG layer.
